(19) United States
(12) Patent Application Publication
(10) Pub. No.: US 2003/0184381 A1
(43) Pub. Date: Oct. 2, 2003

(54) On chip AC coupled circuit

(76) Inventors: Theodore J. Wyman, Mont Vernon, NH (US); Robert James Martin, Orlando, FL (US); Rien Gahlsdorf, Nashua, NH (US)

Correspondence Address: MORGAN & FINNEGAN, L.L.P., 345 Park Avenue, New York, NY, 10154-0053, US

(21) Appl. No.: 10/390,101

(22) Filed: Mar. 17, 2003

Related U.S. Application Data
(60) Provisional application No. 60/365,609, filed on Mar. 18, 2002.

(51) Int. Cl. H03F 3/16

(52) U.S. Cl. 330/277

(57) ABSTRACT

An alternating current coupling circuit is made up of a chip located within a chain of differential amplifier circuits having thereon a) a filter circuit, having an output, the filter circuit being constructed to filter out a direct current component in a low swing alternating current (AC) signal; and b) a current amplifier circuit, connected to the output of the filter, that amplifies a current associated with the AC signal.

### CROSS REFERENCE TO RELATED APPLICATIONS

This application claims priority under 35 USC 119(e)(1) of U.S. Provisional Patent Application Serial No. 60/365,609 filed Mar. 18, 2002.

### FIELD OF THE INVENTION

The present invention relates generally to integrated semiconductor circuits, and relates more particularly to an AC coupling circuit.

### BACKGROUND

In today's operations of integrated circuits, high speed signals have a crucial role as a medium to transmit information. Generally, the high speed signals being used in an IC device are not pure AC waveforms, they have a DC component, creating a DC offset, so that the average of the high speed signal is not zero. Often when sending signals between one IC and another there will be a difference between the DC level outputted by the transmitting chip and the DC level excepted by the receiving chip. In this case it is necessary to block the DC level between one chip and the other chip using AC coupling.

FIG. 3 is a schematic diagram of a typical AC coupling circuit for an IC of the prior art. It is a high pass filter, constructed using capacitor C1 and resistor R1. The cutoff frequency of the AC coupling circuit is given by:

$$f = \frac{1}{2 π RC}$$

where R and C are the resistance and capacitance values of R1 and C1, respectively. In this prior art example, values of 50 ohm and 20 nF were used. The 50 ohm resistance for R1 is chosen to properly terminate the transmission line external to the chip. Then, the capacitance value can be chosen to provide the desired cutoff frequency. For this example, the cutoff frequency is approximately 159 KHz.

This AC coupling circuit of the prior art creates a problem because the AC coupling circuit cannot be fabricated on-chip and be a part of the IC. This is because a 20 nF capacitor is physically much larger than the transistors normally used in the IC, and fabricating the AC coupling circuit on-chip would be a waste of valuable space on the semiconductor substrate, which results in any or such IC being too large physically for its standard application. Currently, the solution to this problem is to connect the AC coupling circuit with the IC externally, so that the AC coupling circuit is connected to the IC on a printed circuit board (PCB). External AC coupling has the drawbacks that it requires PCB space and, increases board cost and complexity.

Another problem which AC coupling can solve is the DC offset in differential amplifier stages. The receiver amplifiers that we use are differential because differential amplifiers have improved noise immunity over single ended amplifiers. In addition they generate reduced power supply switching noise compared to a single ended amplifier. So they both create less noise, and are less susceptible to noise.

A drawback to the real world implementation of differential amplifiers is that it is not possible to exactly match the differential pair in the amplifier over process variation. A typical BJT differential amplifier will have up to 2-3 mV of offset between the two arms. Minimum size CMOS differential pairs have even more offset, on the order of 10-15 mV. Proper layout techniques can be followed to maximize matching of the transistors, but these offsets due to process variation will still exist.

The effects of having an offset in the differential amplifier chain are only problematic before the signal is amplified to the point of the maximum swing achievable by the differential amplifier stage (when the amplifier limits). For a given differential amplifier this is when the swing on each side of the amplifier swings from Vcc to Vcc−(Ic*Rc). Before the amplifier limits offset in the amplifier chain will cause the two arms of the amplifier to have different common mode voltages. Their common modes will come closer together or move further apart depending on the offset of the amplification stage they have just gone through, while each amp stage will increase the swing of the signals. FIG. 1A is an AC signal before offset. FIG. 1B is the signal after offset and amplification.

The problem sets in when the differential signals with different common mode voltage levels cause an amplifier stage to limit. The limiting amplifier will switch when the offset input signals cross each other. This will result in the amplifier switching either sooner or later than it should, and results in duty cycle distortion of the output signal. See FIG. 1C. Duty cycle distortion makes it more difficult for a Clock/Data Recovery (CDR) circuit to accurately capture an input signal. So duty cycle distortion has the effect of increasing the BER (bit error rate) of the amplifier chain.

Differential amplifier chains with sub-limiting signal swings will be more affected by offset the earlier in the chain that the offset occurs.

Techniques to eliminate the effect of the offset in the differential amplifier chain will have the desirable effect of decreasing the chain's BER. Several techniques for doing this are outlined below.

The most straightforward way of correcting for the offset in a chain is to directly compensate for that offset at some point early on in the chain before the largest signal to be amplified by the chain limits. FIG. 2 shows such a circuit. Two FETs 210 and 220 can be tied to either arm of the differential amplifier. The current through these devices can then be adjusted while looking at the output 230 and 240 of the amplifier chain. When the output duty cycle of the chain becomes ˜50% the current setting in the FETs is stored and the output is corrected.

AC coupling of the amplifier chain will also eliminate the effect of offset in the stages of the chain. AC coupling de-couples the DC value of the signal before the AC coupling from the DC value of the signal after the AC coupling. Two differential signals whose common mode values have strayed from one another due to offset will be reset the same common mode value after the AC coupling as determined by the biasing scheme after the AC coupling. The AC coupling itself may have offset in it, and care must be taken to AC couple at the right points in the chain for the signal levels under consideration and to not insert more offset than has been removed.

### SUMMARY OF THE INVENTION

We solve the problems described above with an AC coupling circuit that is small enough so that one or more such circuits can be economically fabricated on-chip.

An aspect of the invention involves an alternating current coupling circuit within an integrated circuit. The circuit has a chip comprising a filter that filters out a direct current component in an alternating current (AC) signal, a matching resistor, connected to the input of the filter, that controls an input impedance of the coupling circuit, and a current amplifier, connected to the output of the filter that amplifies a current associated with the AC signal.

The advantages and features described herein are a few of the many advantages and features available from representative embodiments and are presented only to assist in understanding the invention. It should be understood that they are not to be considered limitations on the invention as defined by the claims, or limitations on equivalents to the claims. For instance, some of these advantages are mutually contradictory, in that they cannot be simultaneously present in a single embodiment. Similarly, some advantages are applicable to one aspect of the invention, and inapplicable to others. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

FIGS. 1A-1C are graphs of signals of the prior art;

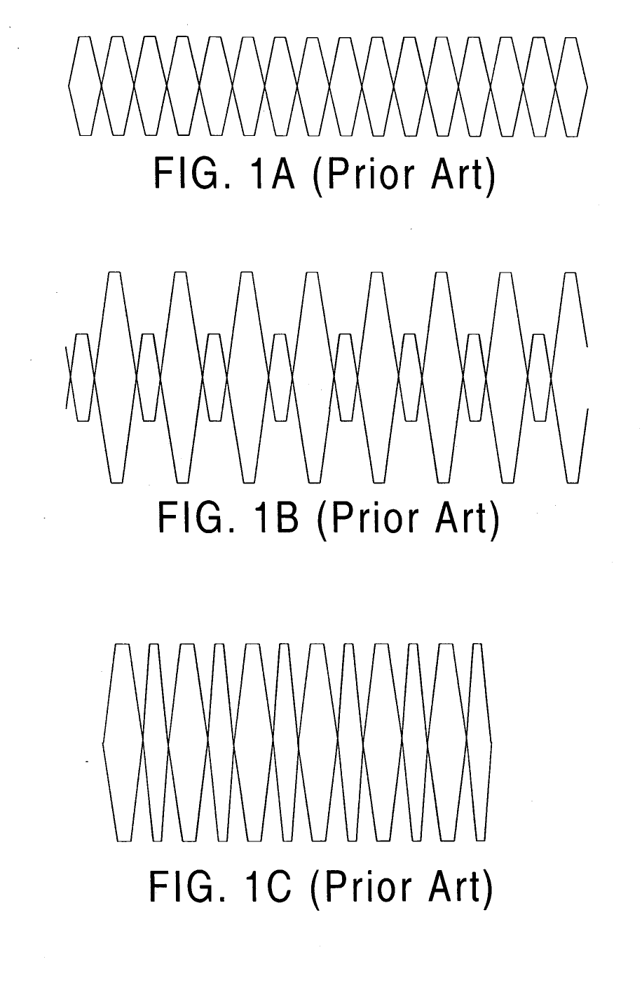

FIG. 2 is a schematic diagram of a circuit to eliminate offset of the prior art;

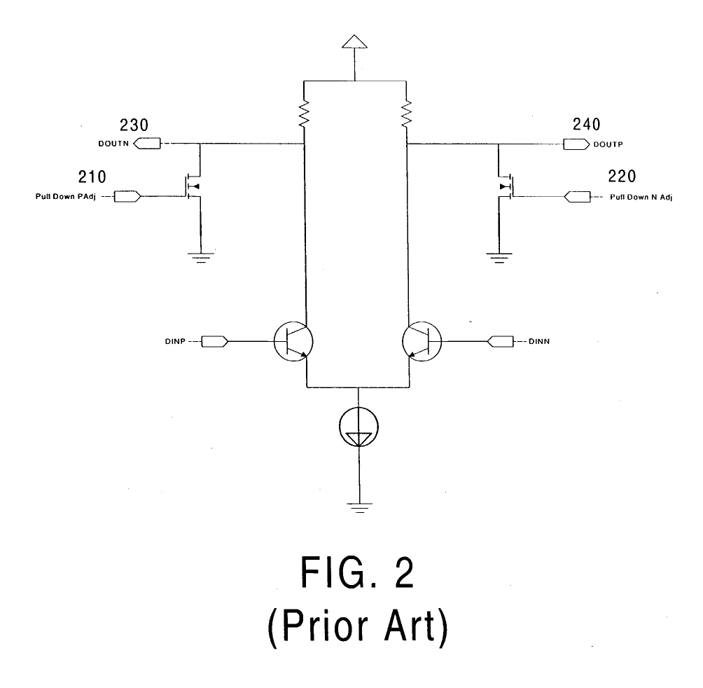

FIG. 3 is a schematic diagram of an AC coupling circuit of the prior art; and

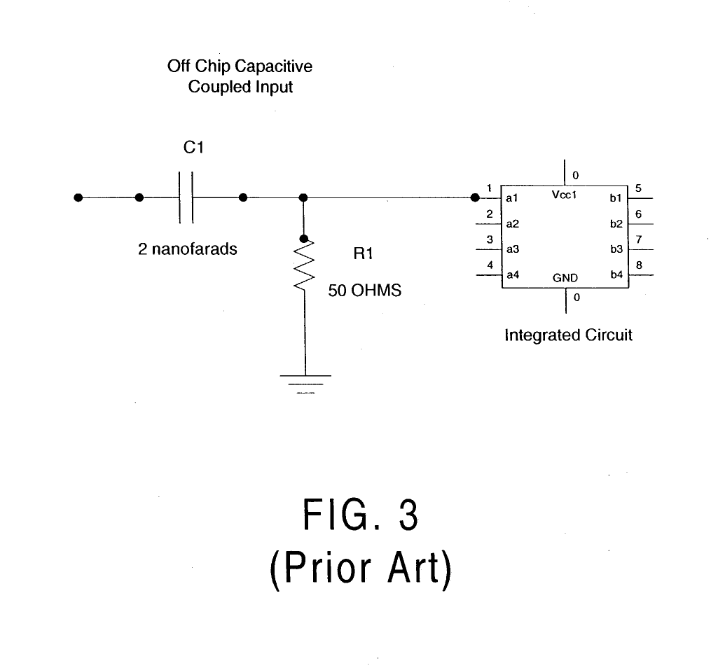

FIG. 4 is a schematic diagram of an example of an on-chip AC coupling circuit connected with an IC in accordance with the present invention.

### DETAILED DESCRIPTION OF THE DRAWINGS

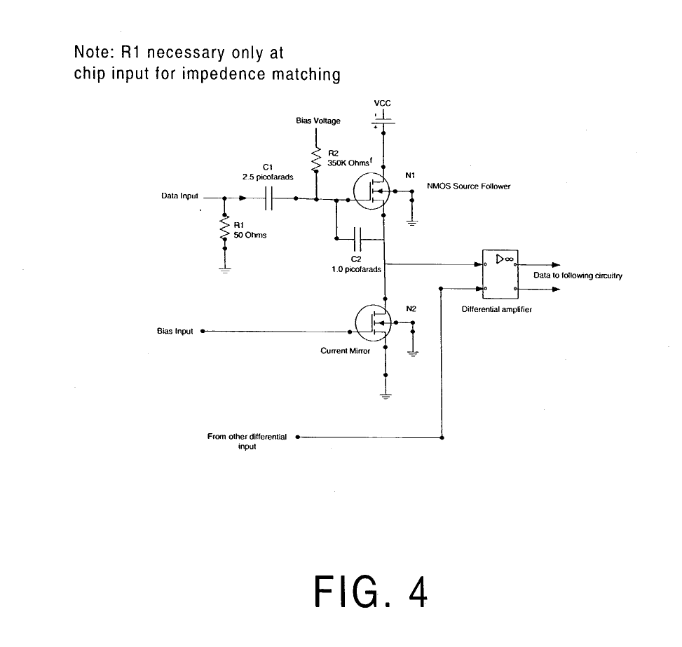

FIG. 4 is a schematic diagram of an example of an on-chip AC coupling circuit connected with an IC in accordance with the present invention. The AC coupling circuit has a high pass filter constructed by C1 and R2. In this example, C1 is a 2.5 pF capacitor and R2 is a 350K ohm resistor. The cutoff frequency is approximately 182 KHz. When the AC coupling cirucit is used at the input of a chip, such a large R2 would introduce improper loading at the input of the AC coupling circuit. Therefore, a matching transistor R1 is connected in front of C1 so that the input impedance of the AC coupling circuit is maintained at 50 ohm. A source follower circuit follows the high pass filter, with the output of the high pass filter connected to the gate of N1 and N2 is used as a current sink. This source follower circuit is used to boost the current of the AC signal after the high pass filter stage. A bypass capacitor C2 is connected to the gate and the source of N1. This bypass capacitor C2 is used so that a high frequency AC signal will not go through N1 but go directly to the input of the IC, in this example the IC is a differential amplifier. This bypass capacitor C2 is added because, at high frequencies, the propagation delay through N1 may otherwise distort the AC signal. The bias voltages at one end of R2 and at the gate of N2 can be adjusted for optimum operation of the AC coupling circuit.

Although an on-chip AC coupling circuit according to the present invention uses more active and passive components than an external AC coupling circuit of the prior art, advantageously, the physical dimensions of an on-chip AC coupling circuit according to the teachings of the present invention is much smaller than used in the circuits of the prior art. The capacitors used in a circuit according to the teachings of the present invention is in the range of 1-2.5 pF, whereas capacitors used in the circuits of prior art are in the range of 10-20 nF. This reduction is size makes it possible to fabricate an AC coupling circuit on-chip, without occupying a large area of space on the semiconductor substrate. Not only does this AC coupling circuit make the overall device more compact, it also makes the PCB where the IC is mounted on less complex and easier to design, and the time response for the IC is improved.

Several components of the on-chip AC coupling circuit of FIG. 4 can be replaced with other devices without compromising the functionality of the overall circuit. For example, the transistors used in the source follower circuit N1 and N2 can be replaced by bipolar junction transistors (BJT). Also, the resistor R2 can be replaced with a long channel PMOS transistor adapted to have a similar function as a resistor, but it would be much smaller in size than a 350 k ohm resistor. And the differential amplifier is used as an exemplary IC in FIG. 4, as the on-chip AC coupling circuit of the present invention can be adapted to function with any IC.

It should be understood that the above description is only representative of illustrative embodiments. For the convenience of the reader, the above description has focused on a representative sample of all possible embodiments, a sample that teaches the principles of the invention. The description has not attempted to exhaustively enumerate all possible variations. That alternate embodiments may not have been presented for a specific portion of the invention, or that further undescribed alternate embodiments may be available for a portion, is not to be considered a disclaimer of those alternate embodiments. One of ordinary skill will appreciate that many of those undescribed embodiments incorporate the same principles of the invention and others are equivalent.

What is claimed is:

1. An electronic circuit comprising:
a single chip comprising
a) an input;
b) a high-pass filter circuit comprising a first capacitor and an output, the high-pass filter circuit being coupled to the input;
c) a source follower circuit coupled to the high pass filter circuit; and
d) a bypass capacitor,
wherein both the first capacitor and the bypass capacitor are in the range of about 1 pF to about 2.5 pF in capacitance.

2. The electronic circuit of claim 1 wherein the single chip circuit includes a field effect transistor.

3. The electronic circuit of claim 2 wherein the field effect transistor is disposed to act as a current mirror.

4. The electronic circuit of claim 2 wherein the field effect transistor is part of the source follower circuit.

5. The electronic circuit of claim 1 further comprising an impedance matching resistor.

6. The electronic circuit of claim 1 wherein the single chip circuit includes a bipolar transistor.

7. The electronic circuit of claim 1 further comprising a long channel PMOS transistor configured to act as a resistor.

8. An alternating current coupling circuit comprising:
a chip located within a chain of differential amplifier circuits having thereon
a) a filter circuit, having an output, the filter circuit being constructed to filter out a direct current component in a low swing alternating current (AC) signal; and
b) a current amplifier circuit, connected to the output of the filter, that amplifies a current associated with the AC signal.

9. The alternating current coupling circuit of claim 8 wherein the current amplifier circuit comprises a pair of NMOS transistors.

10. The alternating current coupling circuit of claim 8 wherein the chip further includes at least two capacitors each having a capacitance of between about 1 pF to about 2.5 pF.
